(19) United States
(12) Patent Application Publication
(10) Pub. No.: US 2006/0044067 A1
(43) Pub. Date: Mar. 2, 2006

(54) High-frequency power amplifier

(75) Inventors: Hidefumi Suzaki, Kusatsu-shi (JP); Jae-Woo Park, Kyunggi-Do (KR); Motoyoshi Iwata, Ibaraki-shi (JP); Yorito Ota, Kobe-shi (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Osaka (JP)

(21) Appl. No.: 11/213,842

(22) Filed: Aug. 30, 2005

(30) Foreign Application Priority Data
Aug. 31, 2004 (JP) 2004-251166

(51) Int. Cl. H03F 3/68

(52) U.S. Cl. 330/295

(57) ABSTRACT

In a high-frequency power amplifier of the present invention, when a short circuit occurs between a gate or source or between a base and emitter in one of unit cells comprising a multi-cell, influence on the operations of the other normal unit cells is suppressed by a direct-current interrupting characteristic of a diode disposed for each of the unit cells.

### FIELD OF THE INVENTION

The present invention relates to a high-frequency power amplifier provided for amplification of a high-frequency signal in a wireless communication terminal used as a fixed terminal of a base station and a mobile terminal such as a mobile phone, the mobile and fixed terminals being used for communications, for example, in a mobile communication system such as a mobile phone system comprised of mobile phones and base stations.

### BACKGROUND OF THE INVENTION

In recent years, mobile communication systems such as a mobile phone system comprised of two or more mobile phones and two or more base stations have been widely used as public phone systems because of the convenience of calls and e-mails on the move. For example, in order to communicate among mobile phones via a base station in such a mobile communication system, wireless communication terminals for communications using high-frequency signals (radio frequency) are used as a fixed terminal of a base station and a mobile terminal such as a mobile phone. In such a wireless communication terminal, a multistage high-frequency multistage power amplifier comprised of one or more stages is generally used to transmit high-frequency signals.

The output power level of the high-frequency power amplifier reaches 200 mW to 3 W in a mobile terminal and reaches 10 W to 100 W in a fixed terminal of a base station. In order to amplify required high-frequency power, a transistor is used which is called a multi-cell and capable of handling higher power. In the transistor, two or more small cells called unit cells are connected in parallel. Unit cells can be added in the multi-cell according to a required output power level.

The multi-cell is comprised of an input terminal, an output terminal, and a ground terminal. When unit cells are comprised of field-effect transistors, the input terminal of the multi-cell is configured by connecting the gate terminals of the two or more unit cells, the output terminal of the multi-cell is configured by connecting the drain terminals of the unit cells, and the ground terminal of the multi-cell is configured by connecting the source terminals of the unit cells. The ground terminal is connected to the ground on a substrate where the unit cells are packaged or integrated.

The conventional high-frequency power amplifier configured thus will be described below with reference to, for example, Japanese Patent Laid-Open No. 2000-323658.

FIG. 7 is an equivalent circuit layout showing an example of the conventional high-frequency power amplifier. As shown in FIG. 7, the high-frequency power amplifier has a single stage where a field-effect transistor is used as a transistor 224. The transistor 224 has a multi-cell configuration in which four unit cells 225, 226, 227, and 228 are connected in parallel. Gate terminals 229, 230, 231, and 232, drain terminals 233, 234, 235, and 236, and source terminals 237, 238, 239, and 240 of the unit cells 225, 226, 227, and 228 are connected with one another among the unit cells, and these terminals comprises an input terminal 241, an output terminal 242, and a ground terminal 243 of the transistor 224.

A bias supply circuit and a matching circuit 247 are connected to the input terminal 241 of the transistor 224. The bias supply circuit is comprised of resistors 244, 245, and 246 for supplying a bias voltage to the gate terminals of the field-effect transistors comprised of the unit cells 225, 226, 227, and 228. The matching circuit 247 transforms an input impedance of the transistor 224 to 50Ω. A bias supply circuit 248 and a matching circuit 249 are connected to the output terminal 242 of the transistor 224. The bias supply circuit 248 is necessary to supply a bias voltage and current to the drain terminals 233, 234, 235, and 236 of the unit cells 225, 226, 227, and 228. The matching circuit 249 transforms an output impedance of the transistor 224 to 50 Ω.

The specific configuration of the conventional high-frequency power amplifier will be discussed below in accordance with the accompanying drawings.

FIG. 8A and FIG. 8B each is a specific structural layout showing the configuration of the conventional high-frequency power amplifier. FIG. 8A is a specific structural layout showing the overall configuration of the conventional high-frequency power amplifier. FIG. 8B is a specific structural layout showing the configuration of an transistor chip in the conventional high-frequency power amplifier. Also in the following explanation, a single-stage high-frequency power amplifier will be discussed as an example. A bipolar transistor is used as a transistor. As shown in FIG. 8A and FIG. 8B, a transistor chip 250 has a multi-cell configuration where four unit cells 251, 252, 253, and 254 are integrated and the transistor chip 250 is bonded to a die pad area 256 formed of metal wires printed on a dielectric substrate 255.

Wires drawn from base terminals 257, 258, 259, and 260 and collector terminals 261, 262, 263, 264, 265, 266, 267, and 268 of the unit cells 251, 252, 253, and 254 are connected to one another on the transistor chip 250. The base side of the unit cells is drawn as an input terminal 269 to a metal wire 271 and the collector side of the unit cells is drawn as an output terminal 270 to a metal wire 272. The metal wires 271 and 272 are printed on the dielectric substrate 255. The emitter terminals of the unit cells 251, 252, 253, and 254 are connected to the die pad area 256 through via holes 273, 274, 275, and 276 formed on the transistor chip 250. The die pad area 256 is grounded.

A bias supply circuit 280 and a matching circuit 281 are connected to wires drawn from the input terminal 269 of the transistor chip 250. The bias supply circuit 280 is comprised of resistors 277, 278, and 279 for supplying a bias current to the base terminals 257, 258, 259, and 260 of the four unit cells. The matching circuit 281 transforms an input impedance of the transistor chip 250 to 50 Ω.

A bias supply circuit 282 and a matching circuit 283 are connected to wires drawn from the output terminal 270 of the transistor chip 250. The bias supply circuit 282 is necessary to supply a bias voltage and current to the collector terminals of the four unit cells. The matching circuit 283 transforms an output impedance of the transistor chip 250 to 50 Ω.

In such a mobile communication system including a mobile phone network, a high performance operation and high reliability are demanded of a high-frequency power amplifier used for a transmission section of a wireless communication terminal of a base station or a mobile terminal. Generally, in transistors used for high-frequency power amplifiers, two or more small transistors called unit cells are configured in parallel to obtain higher output performance, thereby securing electric energy to be handled. A high performance operation and high reliability are demanded of the unit cells. Generally, the mean time to failure (MTTF) of a transistor used for a unit cell sufficiently exceeds 10⁶ hours, which is far longer than service life demanded of a high-frequency power amplifier.

However, such a conventional high-frequency power amplifier may cause a failure in some service conditions. For example, a unit cell may be broken due to an extended period of use at high temperature and high humidity, a lightening strike, static electricity generated from a human body, or fluctuations in power supply voltage.

Such a case will be discussed below with reference to the example of the conventional high-frequency power amplifier shown in FIG. 7.

The four unit cells 225, 226, 227, and 228 are configured in the transistor 224. A failure of any one of the four unit cells may disable the high-frequency power amplifier to perform its function. The used transistor is a field-effect transistor. In the case of the transistor of the high-frequency power amplifier used in a mobile terminal of a mobile communication system and a fixed terminal of a base station, a GaAs MESFET or the like is frequently used which has excellent basic performance and high reliability in a high-frequency area. Since this device is a normally-on device, when a proper voltage is not applied to the gate terminal for any reason, nothing interferes with current between the drain and source and causes a drain current exceeding a rated current, so that the device may be broken.

When the used transistor is a bipolar transistor, in the event of a short circuit between the base and emitter in a broken unit cell, a base current distributed to all the unit cells flows to GND through the broken cell. Thus, all the unit cells may be interrupted and an amplifying function may be stopped.

Also in the conventional high-frequency power amplifier, a proper voltage or current can be applied to the gate terminals or base terminals of the unit cells. However, when a failure occurs on any one of the two or more unit cells which comprise the high-frequency power amplifier and are connected in parallel and a failure mode is a short circuit between the gate and source or between the base and emitter, a proper bias cannot be applied to a normal unit cell sharing its gate terminal or base terminal with the broken unit cell, thereby disabling control of a drain current and a collector current.

As a result, a drain current far exceeding the rated current is applied and may result in burning of the high-frequency power amplifier, burning of a power supply channel, unexpected oscillation due to unstable operations caused by fluctuations in operating current, unreasonable noise, and stopped transmission of signals, which can lead to a system failure. The occurrence of such accidents causes a considerable loss.

### DISCLOSURE OF THE INVENTION

The present invention is devised to solve the conventional problem. An object of the present invention is to provide a high-frequency power amplifier whereby even in the event of a short circuit between the gate and source or between the base and emitter of one unit cell, it is possible to obtain a highly reliable operation while enabling normal unit cells to keep a stable high-performance operation, without causing burning of an amplifier, burning of a power supply channel, or fluctuations in operating current.

A high-frequency power amplifier of the present invention is a high-frequency power amplifier provided for power amplification of a high-frequency signal in a communication terminal for communications via the high-frequency signal. The high-frequency power amplifier includes a transistor to amplify power of the high-frequency signal in a multistage configuration of one or more stages, wherein the transistor includes a multi-cell having at least two or more unit cells connected in parallel in each stage, the drain terminals or collector terminals of the unit cells are connected to one another to form an output terminal of the multi-cell, the source terminals or emitter terminals of the unit cells are connected to one another to form a ground terminal of the multi-cell, and the gate terminals or base terminals of the unit cells are connected via diodes to form an input terminal of the multi-cell, the diode being disposed for each of the unit cells.

In the transistor, the diodes respectively disposed for the unit cells are connected in series at least in a pair in the opposite polarity directions when one of the unit cells is viewed from the other between the gate terminals or base terminals of the adjacent unit cells.

The transistor has a field-effect transistor instead of the diode disposed for each of the unit cells.

The transistor has a bipolar transistor instead of the diode disposed for each of the unit cells.

With this configuration, at least a pair of forward diode and a reverse diode is always connected in series between the adjacent unit cells. Thus, even in the event of a failure on one of the unit cells, it is possible to almost eliminate influence to a bias voltage or current applied to the gate terminals or base terminals of the adjacent unit cells and continuously apply a proper bias without breaking the adjacent normal unit cells.

The operations of the normally operating unit cells are continued without losing all the functions of the unit cells, so that it is possible to minimize influence on a system and obtain high reliability while keeping a high-performance operation.

When a used frequency band is a high-frequency region in or above the UHF band, the parasitic capacitance of the diode is sufficiently large, and thus it is possible to interrupt a direct current and allow only the transit of an alternating signal without using an alternating bypass unit such as a capacitor, which is disadvantageous to miniaturization.

Hence, it is possible to obtain higher reliability while keeping a high-performance operation with a small size and at low cost.

Further, because of a diode characteristic between the gate and drain and between the base and collector in the transistor, even in the event of a failure on some of the unit cells, it is possible to prevent influence on an operating state of an adjacent normal unit cell. Additionally, even when an alternating signal exceeding a rated current is inputted to the amplifier for any reason, the transistor having been turned off in a stable operation is turned on by the voltage or current amplitude of the inputted signal, the bias voltage or current of the transistor is bypassed, and the operating point of the transistor can be automatically reduced.

Thus, it is possible to prevent excessive current from flowing to the transistor, thereby obtaining high reliability while keeping a high-performance operation.

Moreover, because of a diode characteristic between the gate and source and between the base and emitter in the transistor, even in the event of a failure on some of the unit cells, it is possible to prevent influence on an operating state of the adjacent normal unit cells. Further, when an alternating signal inputted to the transistor reaches a certain level, the transistor is turned on and a bias voltage or current is added to the transistor by a direct-current power supply applied to the drain terminal and the collector terminal, so that the operation of the transistor can be shifted from class B operation to class A operation according to the level of the signal inputted to the amplifier. Hence, it is possible to automatically switch the operation modes of the transistor. For example, the operation is switched to B class operation at low power and switched to A class operation at high power.

Therefore, it is possible to improve the linearity of the high-frequency power amplifier and realize higher performance and higher reliability for a communication system which uses a digital modulation scheme requiring high linearity.

As described above, even in the event of a short circuit between the gate and source or between the base and emitter in one of the unit cells, it is possible to secure a highly reliable operation while enabling normal unit cells to stably keep a high-performance operation, without causing burning of the amplifier, burning of a power supply channel, or fluctuations in operating current.

### BRIEF DESCRIPTION OF THE DRAWINGS

FIG. 1 is an equivalent circuit layout showing a structural example of a high-frequency power amplifier according to Embodiment 1 of the present invention;

FIG. 2A is a specific structural layout showing a structural example of a high-frequency power amplifier according to Embodiment 2 of the present invention;

FIG. 2B is a specific structural layout showing a structural example of a high-frequency power amplifier according to Embodiment 2 of the present invention;

FIG. 3 is an equivalent circuit layout showing a structural example of a high-frequency power amplifier according to Embodiment 3 of the present invention;

FIG. 4 is an equivalent circuit layout showing a structural example of a high-frequency power amplifier according to Embodiment 4 of the present invention;

FIG. 5 is an equivalent circuit layout showing a structural example of a high-frequency power amplifier according to Embodiment 5 of the present invention;

FIG. 6 is an equivalent circuit layout showing a structural example of a high-frequency power amplifier according to Embodiment 6 of the present invention;

FIG. 7 is an equivalent circuit layout showing a structural example of a conventional high-frequency power amplifier; and

FIG. 8A is a specific structural layout showing a configuration of the conventional high-frequency power amplifier; and

FIG. 8B is a specific structural layout showing a configuration of the conventional high-frequency power amplifier.

### DESCRIPTION OF THE EMBODIMENTS

High-frequency power amplifiers showing embodiments of the present invention will be specifically discussed below with reference to the accompanying drawings.

### Embodiment 1

A high-frequency power amplifier will be discussed below according to Embodiment 1 of the present invention.

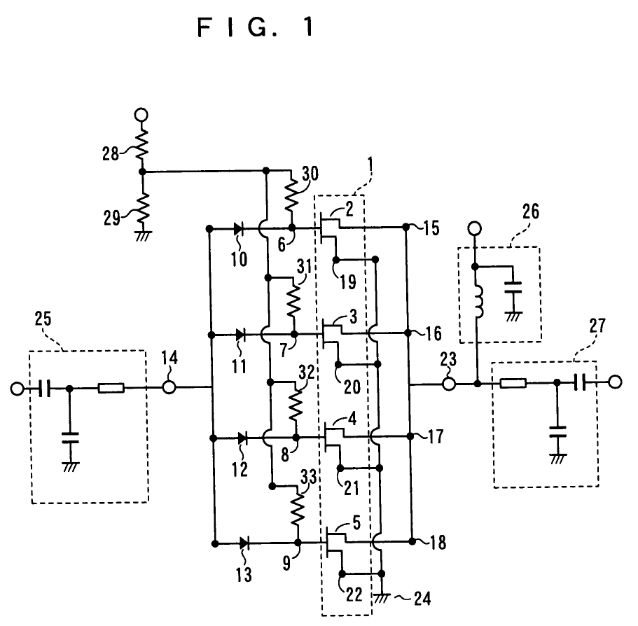

FIG. 1 is an equivalent circuit layout showing a structural example of the high-frequency power amplifier according to Embodiment 1. As shown in FIG. 1, the high-frequency power amplifier of Embodiment 1 has a single stage of a transistor 1 which is a field-effect transistor. The transistor 1 has a multi-cell configuration where four unit cells 2, 3, 4, and 5 are connected in parallel. Diodes 10, 11, 12, and 13 are connected to gate terminals 6, 7, 8, and 9 of the unit cells 2, 3, 4, and 5.

The diodes 10, 11, 12, and 13 are all connected in the same direction with respect to the gate terminals 6, 7, 8, and 9 of the unit cells 2, 3, 4, and 5. The other ends of the diodes 10, 11, 12, and 13 connected to the unit cells 2, 3, 4, and 5 are connected to one another and comprise an input terminal 14 of the transistor 1. As a result, between the gate terminal of one unit cell and the gate terminal of another adjacent unit cell, a pair of forward diode and a reverse diode is always connected in series. Drain terminals 15, 16, 17, and 18 and source terminals 19, 20, 21, and 22 are connected to one another. The drain terminals and the source terminals respectively comprise an output terminal 23 and a ground terminal 24 of the transistor 1.

A matching circuit 25 to transform an input impedance of the transistor 1 to 50 Ω is connected to the input terminal 14 of the transistor 1. A bias supply circuit 26 and a matching circuit 27 are connected to the output terminal 23 of the transistor 1. The bias supply circuit 26 is necessary to supply a bias voltage and current to the drain terminals 15, 16, 17, and 18 of the unit cells 2, 3, 4, and 5. The matching circuit 27 transforms an output impedance of the transistor 1 to 50 Ω.

A bias supply circuit comprised of resistors 28, 29, 30, 31, 32, and 33 is connected to the gate terminals 6, 7, 8, and 9 of the unit cells 2, 3, 4, and 5 to supply a bias voltage to the gate terminals of field-effect transistors comprising the unit cells. In the present embodiment, the diodes 10, 11, 12, and 13 are inserted on the gate terminals 6, 7, 8, and 9 of the unit cells, and thus the resistors 30, 31, 32, and 33 of the resistors comprising the bias supply circuit are disposed near the gate terminals 6, 7, 8, and 9, so that a proper bias voltage can be applied.

### Embodiment 2

A high-frequency power amplifier will be discussed below according to Embodiment 2 of the present invention.

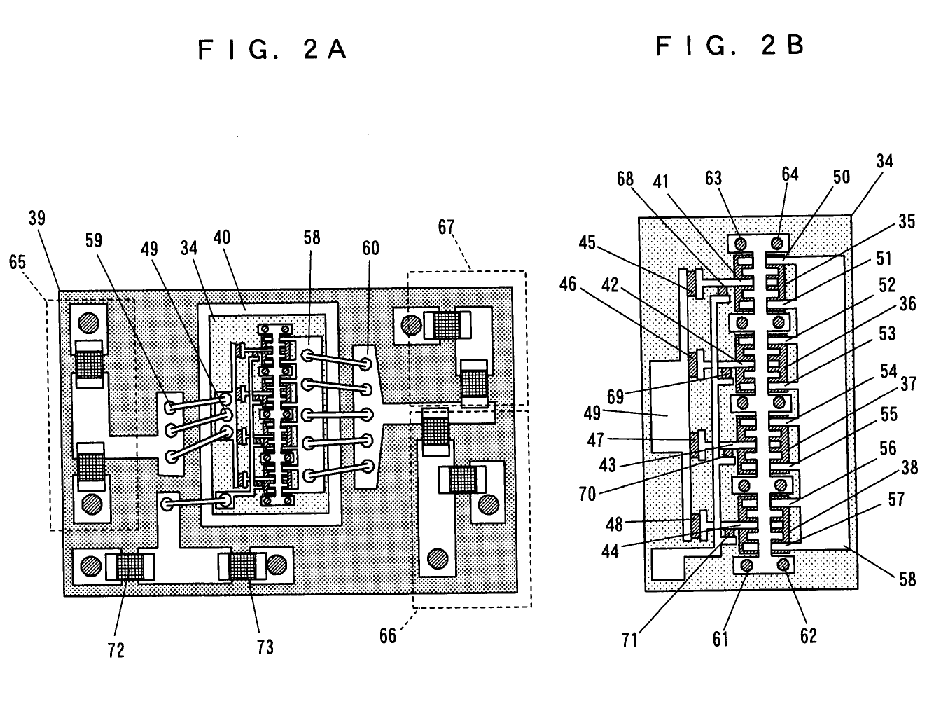

FIG. 2A and FIG. 2B each is a specific structural layout showing a structural example of the high-frequency power amplifier according to Embodiment 2. As shown in FIG. 2A and FIG.2B, the high-frequency power amplifier of Embodiment 2 has a single stage of a transistor which is a bipolar transistor. A transistor chip 34 has a multi-cell configuration where four unit cells 35, 36, 37, and 38 are connected in parallel and the transistor chip 34 is bonded to a die pad area 40 formed of metal wires printed on a dielectric substrate 39. Diodes, 45, 46, 47, and 48 are connected to base terminals 41, 42, 43, and 44 of the unit cells 35, 36, 37, and 38, respectively.

The diodes 45, 46, 47, and 48 are all connected in the same direction with respect to the base terminals 41, 42, 43, and 44 of the unit cells 35, 36, 37, and 38. The other ends of the diodes 45, 46, 47, and 48 connected to the unit cells 35, 36, 37, and 38 are connected to one another and comprise an input terminal 49 of the transistor ship 34. Wires drawn from collector terminals 50, 51, 52, 53, 54, 55, 56, and 57 are connected to one another on the transistor chip 34 and comprise an output terminal 58. The input terminal 49 and the output terminal 58 are drawn through lead wires to metal wires 59 and 60 printed on the dielectric substrate 39. The emitter terminals of the unit cells 35, 36, 37, and 38 are connected to the die pad area 40 through via holes 61, 62, 63, and 64 formed on the transistor chip 34. The die pad area 40 is normally grounded.

Wires drawn from the input terminal 49 of the transistor chip 34 are connected to a matching circuit 65 to transform an input impedance of the transistor chip 34 to 50 Ω. Wires drawn from the output terminal 58 of the transistor chip 34 are connected to a bias supply circuit 66 for supplying a bias voltage and current to the collector terminals of the four unit cells and a matching circuit 67 to transmit an output impedance of the transistor chip 34 to 50 Ω.

Resistors 68, 69, 70, and 71 are connected to the base terminals 41, 42, 43, and 44 of the unit cells 35, 36, 37, and 38 to supply a bias current to the base terminals of bipolar transistors comprising the unit cells. In the present embodiment, the diodes 45, 46, 47, and 48 are inserted on the base terminals 41, 42, 43, and 44 of the unit cells, and thus the resistors 68, 69, 70, and 71 comprising a bias circuit are formed in the transistor chip 34 and resistors 72 and 73 are disposed on the dielectric substrate 39, so that a proper bias voltage can be applied.

### Embodiment 3

A high-frequency power amplifier will be discussed below according to Embodiment 3 of the present invention.

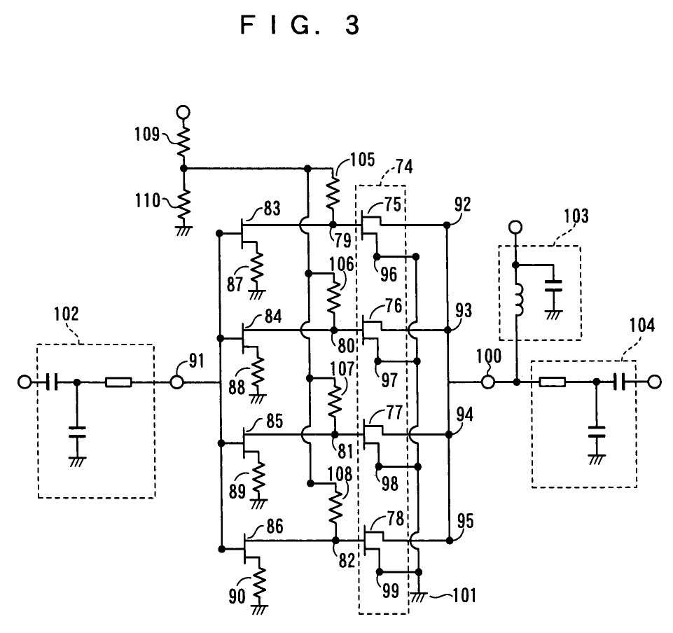

FIG. 3 is an equivalent circuit layout showing a structural example of the high-frequency power amplifier according to Embodiment 3. As shown in FIG. 3, the high-frequency power amplifier of Embodiment 3 has a single stage of a transistor 74. Unit cells comprising the transistor 74 are field-effect transistors. The transistor 74 has a multi-cell configuration where four unit cells 75, 76, 77, and 78 are connected in parallel. The drain terminals of field-effect transistors 83, 84, 85, and 86 are connected to gate terminals 79, 80, 81, and 82 of the unit cells 75, 76, 77, and 78, respectively. The source terminals of the field-effect transistors 83, 84, 85, and 86 are connected to resistors 87, 88, 89, and 90, respectively. The other ends of the resistors 87, 88, 89, and 90 are grounded. The gate terminals of the field-effect transistors 83, 84, 85, and 86 are connected to one another and comprise an input terminal 91 of the transistor 74. Drain terminals 92, 93, 94, and 95 of the unit cells 75, 76, 77, and 78 are connected to one another and source terminals 96, 97, 98, and 99 of the unit cells 75, 76, 77, and 78 are connected to one another. The drain terminals and the source terminals respectively comprise an output terminal 100 and a ground terminal 101 of the transistor 74.

A matching circuit 102 to transform an input impedance of the transistor 74 to 50 Ω is connected to the input terminal 91 of the transistor 74. A bias supply circuit 103 and a matching circuit 104 are connected to the output terminal 100 of the transistor 74. The bias supply circuit 103 is necessary to supply a bias voltage and current to the drain terminals 92, 93, 94, and 95 of the unit cells 75, 76, 77, and 78. The matching circuit 104 transforms an output impedance of the transistor 74 to 50 Ω.

A bias supply circuit comprised of resistors 105, 106, 107, 108, 109, and 110 is connected to the gate terminals 79, 80, 81, and 82 of the unit cells 75, 76, 77, and 78 to supply a bias voltage to the gate terminals of field-effect transistors comprising the unit cells. In the present embodiment, the field-effect transistors 83, 84, 85, and 86 are inserted on the gate terminals 79, 80, 81, and 82 of the unit cells 75, 76, 77, and 78. In order to apply a bias as in the conventional art, the resistors 105, 106, 107, and 108 of the resistors comprising the bias supply circuit are disposed near the gate terminals 79, 80, 81, and 82.

### Embodiment 4

A high-frequency power amplifier will be discussed below according to Embodiment 4 of the present invention.

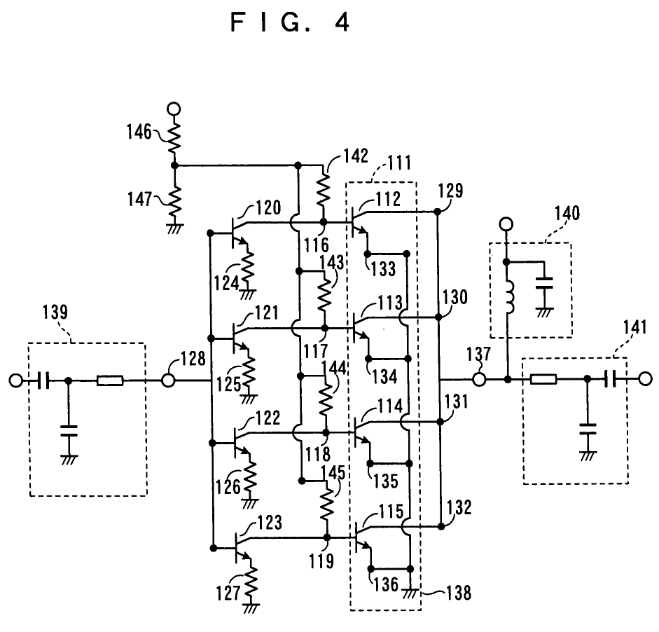

FIG. 4 is an equivalent circuit layout showing a structural example of the high-frequency power amplifier according to Embodiment 4. As shown in FIG. 4, the high-frequency power amplifier of Embodiment 4 has a single stage of a transistor 111. Unit cells comprising the transistor 111 are bipolar transistors. The transistor 111 has a multi-cell configuration where four unit cells 112, 113, 114, and 115 are connected in parallel. The collector terminals of bipolar transistors 120, 121, 122, and 123 are connected to base terminals 116, 117, 118, and 119 of the unit cells 112, 113, 114, and 115, respectively. The emitter terminals of the bipolar transistors 120, 121, 122, and 123 are connected to resistors 124, 125, 126, and 127, respectively. The other ends of the resistors 124, 125, 126, and 127 are grounded.

The base terminals of the bipolar transistors 120, 121, 122, and 123 are connected to one another and comprise an input terminal 128 of the transistor 111. Collector terminals 129, 130, 131, and 132 of the unit cells 112, 113, 114, and 115 are connected to one another and emitter terminals 133, 134, 135, and 136 of the unit cells 112, 113, 114, and 115 are connected to one another. The collector terminals and the emitter terminals respectively comprise an output terminal 137 and a ground terminal 138 of the transistor 111.

A matching circuit 139 to transform an input impedance of the transistor 111 to 50 Ω is connected to the input terminal 128 of the transistor 111. A bias supply circuit 140 and a matching circuit 141 are connected to the output terminal 137 of the transistor 111. The bias supply circuit 140 is necessary to supply a bias voltage and current to the collector terminals 129, 130, 131, and 132 of the unit cells 112, 113, 114, and 115. The matching circuit 141 transforms an output impedance of the transistor 111 to 50 Ω.

A bias supply circuit comprised of resistors 142, 143, 144, 145, 146, and 147 is connected to the base terminals 116, 117, 118, and 119 of the unit cells 112, 113, 114, and 115 to supply a bias current to the bipolar transistors comprising the unit cells. In the present embodiment, the bipolar transistors 120, 121, 122, and 123 are inserted on the base terminals 116, 117, 118, and 119 of the unit cells. In order to apply a bias as in the conventional art, the resistors 142, 143, 144, and 145 of the resistors comprising the bias supply circuit are disposed near the base terminals 116, 117, 118, and 119.

### Embodiment 5

A high-frequency power amplifier will be discussed below according to Embodiment 5 of the present invention.

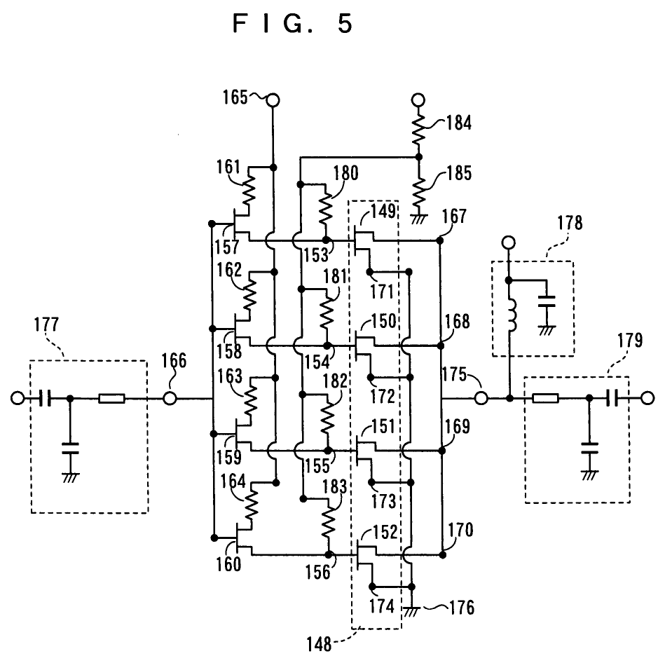

FIG. 5 is an equivalent circuit layout showing a structural example of the high-frequency power amplifier according to Embodiment 5. As shown in FIG. 5, the high-frequency power amplifier of Embodiment 5 has a single stage of a transistor 148. Unit cells comprising the transistor 148 are field-effect transistors. The transistor 148 has a multi-cell configuration where four unit cells 149, 150, 151, and 152 are connected in parallel. The source terminals of field-effect transistors 157, 158, 159, and 160 are connected to gate terminals 153, 154, 155, and 156 of the unit cells 149, 150, 151, and 152. A bias circuit comprised of resistors 161, 162, 163 and 164 is connected to the drain terminals of the field-effect transistors 157, 158, 159, and 160. A direct-current power supply 165 is connected to the other ends of the resistors 161, 162, 163 and 164.

The gate terminals of the field-effect transistors 157, 158, 159 and 160 are connected to one another and comprise an input terminal 166 of the transistor 148. Drain terminals 167, 168, 169, and 170 of the unit cells 149, 150, 151, and 152 are connected to one another and source terminals 171, 172, 173, and 174 of the unit cells 149, 150, 151, and 152 are connected to one another. The drain terminals and the source terminals respectively comprise an output terminal 175 and a ground terminal 176 of the transistor 148.

A matching circuit 177 to transform an input impedance of the transistor 148 to 50 Ω is connected to the input terminal 166 of the transistor 148. A bias supply circuit 178 and a matching circuit 179 are connected to the output terminal 175 of the transistor 148. The bias supply circuit 178 is necessary to supply a bias voltage and current to the drain terminals 167, 168, 169, and 170 of the unit cells 149, 150, 151, and 152. The matching circuit 179 transforms an output impedance of the transistor 148 to 50 Ω.

A bias supply circuit comprised of resistors 180, 181, 182, 183, 184, and 185 is connected to the gate terminals 153, 154, 155, and 156 of the unit cells 149, 150, 151, and 152 to supply a bias voltage to the gate terminals of field-effect transistors comprising the unit cells. In the present embodiment, the field-effect transistors 157, 158, 159, and 160 are inserted on the gate terminals 153, 154, 155, and 156 of the unit cells. In order to apply a bias as in the conventional art, the resistors 180, 181, 182, and 183 of the resistors comprising the bias supply circuit are disposed near the gate terminals 153, 154, 155, and 156.

### Embodiment 6

A high-frequency power amplifier will be discussed below according to Embodiment 6 of the present invention.

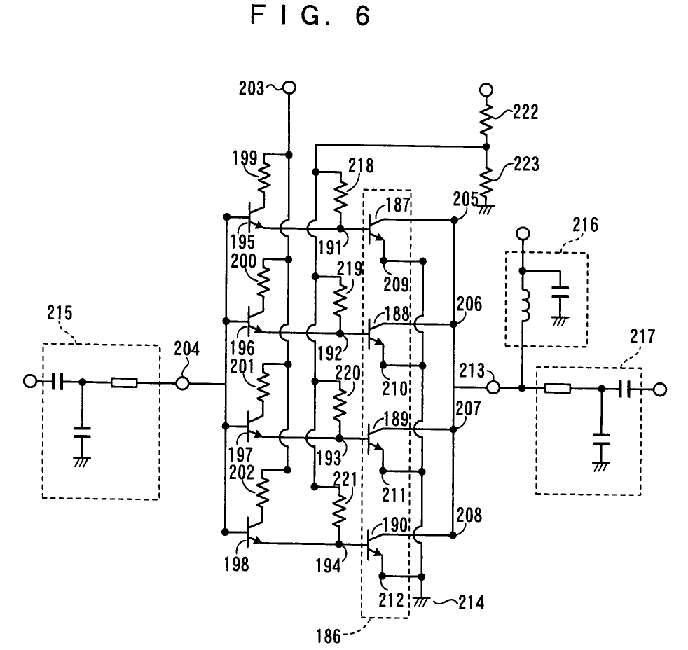

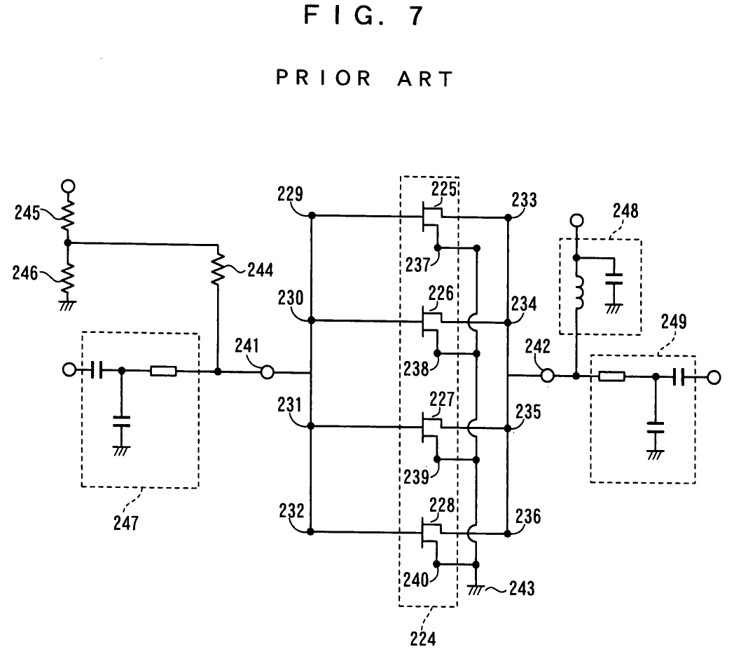

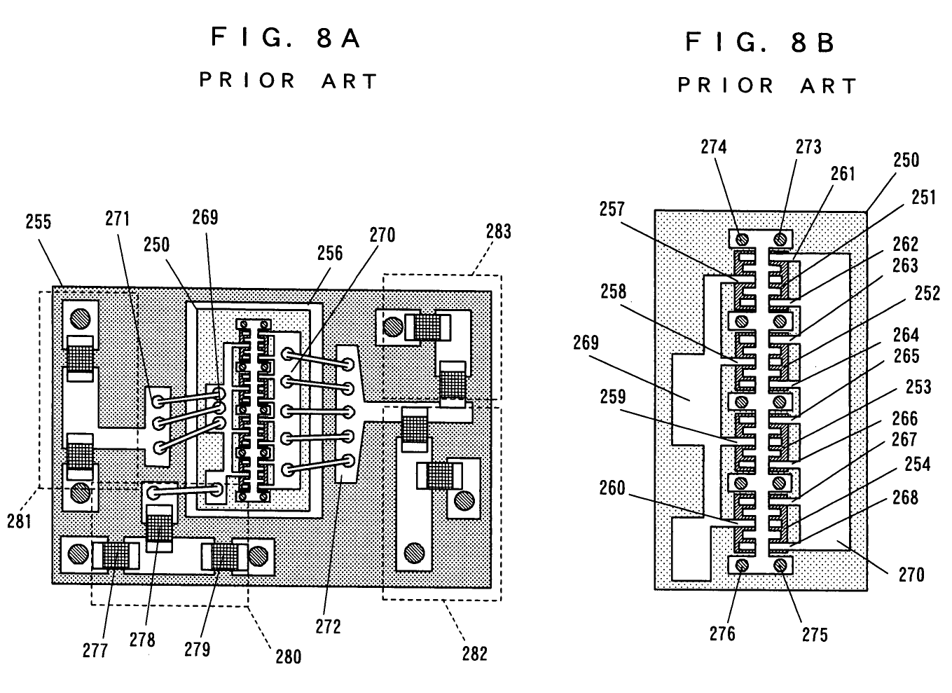

FIG. 6 is an equivalent circuit layout showing a structural example of the high-frequency power amplifier according to Embodiment 6. As shown in FIG. 6, the high-frequency power amplifier of Embodiment 6 has a single stage of a transistor 186. Unit cells comprising the transistor 186 are bipolar transistors. The transistor 186 has a multi-cell configuration where four unit cells 187, 188, 189, and 190 are connected in parallel. The emitter terminals of bipolar transistors 195, 196, 197, and 198 are connected to base terminals 191, 192, 193, and 194 of the unit cells 187, 188, 189, and 190, respectively. A bias circuit comprised of resistors 199, 200, 201 and 202 is connected to the collector terminals of the bipolar transistors 195, 196, 197, and 198. A direct-current power supply 203 is connected to the other ends of the resistors 199, 200, 201 and 202.

The base terminals of the bipolar transistors 195, 196, 197, and 198 are connected to one another and comprise an input terminal 204 of the transistor 186. Collector terminals 205, 206, 207, and 208 of the unit cells 187, 188, 189, and 190 are connected to one another and emitter terminals 209, 210, 211, and 212 of the unit cells 187, 188,189, and 190 are connected to one another. The collector terminals and the emitter terminals respectively comprise an output terminal 213 and a ground terminal 214 of the transistor 186.

A matching circuit 215 to transform an input impedance of the transistor 186 to 50 Ω is connected to the input terminal 204 of the transistor 186. A bias supply circuit 216 and a matching circuit 217 are connected to the output terminal 213 of the transistor 186. The bias supply circuit 216 is necessary to supply a bias voltage and current to the collector terminals 205, 206, 207, and 208 of the unit cells 187, 188, 189, and 190. The matching circuit 217 transforms an output impedance of the transistor 186 to 50 Ω.

A bias supply circuit comprised of resistors 218, 219, 220, 221, 222, and 223 is connected to the base terminals 191, 192, 193, and 194 of the unit cells 187, 188, 189, and 190 to supply a bias voltage to the base terminals of bipolar transistors comprising the unit cells. In the present embodiment, the bipolar transistors 195, 196, 197, and 198 are inserted on the base terminals 191, 192, 193, and 194 of the unit cells. In order to apply a bias as in the conventional art, the resistors 218, 219, 220, and 221 of the resistors comprising the bias supply circuit are disposed near the base terminals 191, 192, 193, and 194.

What is claimed is:

1. A high-frequency power amplifier provided for amplification of a high-frequency signal in a communication terminal for communication via the high-frequency signal, comprising a transistor to amplify the high-frequency signal in a multistage configuration of one or more stages, wherein
the transistor comprises a multi-cell having at least two or more unit cells connected in parallel in each stage, and the unit cells comprise drain terminals or collector terminals connected to one another to form an output terminal of the multi-cell, source terminals or emitter terminals connected to one another to form a ground terminal of the multi-cell, and gate terminals or base terminals connected via diodes to form an input terminal of the multi-cell, the diode being disposed for each of the unit cells.

2. The high-frequency power amplifier according to claim 1, wherein in the transistor, the diodes respectively disposed for the unit cells are connected in series at least in a pair in opposite polarity directions when one of the unit cells is viewed from the other between the gate terminals or base terminals of the adjacent unit cells.

3. The high-frequency power amplifier according to claim 1, wherein the transistor has a field-effect transistor instead of the diode disposed for each of the unit cells.

4. The high-frequency power amplifier according to claim 1, wherein the transistor has a bipolar transistor instead of the diode disposed for each of the unit cells.

5. The high-frequency power amplifier according to claim 3, wherein in the transistor, the field-effect transistor disposed for each of the unit cells has a drain terminal connected to the gate terminal or the base terminal of the unit cell and a source terminal grounded via a resistor, and gate terminals of the field-effect transistors are connected to one another to form the input terminal of the multi-cell.

6. The high-frequency power amplifier according to claim 4, wherein in the transistor, the bipolar transistor disposed for each of the unit cells has a collector terminal connected to the gate terminal or the base terminal of the unit cell and an emitter terminal grounded via a resistor, and base terminals of the bipolar transistors are connected to one another to form the input terminal of the multi-cell.

7. The high-frequency power amplifier according to claim 3, wherein in the transistor, the field-effect transistor disposed for each of the unit cells has a source terminal connected to the gate terminal or the base terminal of the unit cell and a drain terminal connected to a direct-current power supply via a bias circuit, and gate terminals of the field-effect transistors are connected to one another to form the input terminal of the multi-cell.

8. The high-frequency power amplifier according to claim 4, wherein in the transistor, the bipolar transistor disposed for each of the unit cells has an emitter terminal connected to the gate terminal or the base terminal of the unit cell and a collector terminal connected to a direct-current power supply via a bias circuit, and base terminals of the bipolar transistors are connected to one another to form the input terminal of the multi-cell.
